(19) United States
(12) Patent Application Publication
(10) Pub. No.: US 2002/0024138 A1
(43) Pub. Date: Feb. 28, 2002

(54) Wiring board for high dense mounting and method of producing the same

(75) Inventors: Tadanori Shimoto, Tokyo (JP); Koji Matsui, Tokyo (JP); Katsumi Kikuchi, Tokyo (JP)

Correspondence Address: YOUNG & THOMPSON, 745 SOUTH 23RD STREET 2ND FLOOR, ARLINGTON, VA, 22202

(73) Assignee: NEC Corporation

(21) Appl. No.: 09/922,766

(22) Filed: Aug. 7, 2001

(30) Foreign Application Priority Data
Aug. 7, 2000 (JP) 2000-238967

(51) Int. Cl. H01L 23/48

(52) U.S. Cl. 257/753

(57) ABSTRACT

A wiring board for high dense mounting comprises at least one layer of interlayer insulator and at least one layer of conductive wiring pattern formed on a base material. The interlayer insulator comprises a polybenzoxazole film. An adhesive layer comprising at least one selected from the group consisting of Ti, Ti-containing compounds and Ni is formed between the polybenzoxazole film and the conductive wiring pattern. The wiring board has a high heat resistance, low dielectric constant, low water absorption degree, low thermal expansion coefficient, and high adhesion between conductors and insulators. The wiring board is also excellent in film strength and shear extensibility, capable of enduring a stress in mounting of a semiconductor device, excellent in reliability, and optimal for high speed and high dense mounting.

### BACKGROUND OF THE INVENTION

1. Field of the Invention

The present invention relates to a wiring board for high dense mounting. More particularly, the present invention relates to a wiring board optimum for mounting semiconductor devices thereon in a high density to realize a high speed and high dense module or system.

2. Description of the Related Art

As semiconductor devices can be produced to achieve relatively higher speed and integration, wiring boards for mounting these semiconductor devices are required to include such interlayer insulators and passivation films that have various properties, for example, a heat resistance sufficient for solder reflowing and repairing semiconductor devices. The properties also include a low dielectric constant for achieving a high-speed transmission as well as a low water absorption degree, low thermal expansion coefficient, high adhesion between conductors and insulators, high film strength and excellent shear extensibility for achieving excellent reliability.

Proposed interlayer insulators and passivation films for use in wiring boards include polyimide resins (for example, JP 4-284455A and JP 5-165217A publications) and organic silicon resins (for example, JP 3-043455A, JP 4-046934A, JP 6-130364A and JP 7-022508A publications).

The above-mentioned polyimide resins, with condensation water in curing reaction, have a large shrinkage percentage when they are cured. Therefore, they provide poor planarization of wiring steps and accordingly are difficult in formation of wiring boards with a high precision and density. In addition, a large shrinkage stress occurs. As a result, cracks occur in a film if it is multi-layered. Further, Cu ions migrate into the polyimide resin. Thus, a problem arises in reliability on insulation if low resistance Cu is applied as a conductive material.

The above-mentioned organic silicon resins have no more serious shrinkage at the time of curing than the polyimide resins but have a large water absorption degree due to introduction of a silicon group. This causes a problem in reliability on moisture resistance. The introduction of the silicon group also increases a thermal expansion coefficient such that a large stress causes cracks in the wiring board when a semiconductor device is mounted thereon.

On the other hand, proposed interlayer insulators with no shrinkage stress and an excellent moisture resistance include benzocyclobutene resins (for example, JP 4-167596A publication) and epoxyacrylate resins having a fluorene skeleton (for example, JP 9-214141A publication). These resins, in contrast to the polyimide resins, have no ion migration with Cu and can form Cu wires with an excellent cost performance without a barrier metal. In addition, in contrast to the polyimide resins, they have a low shrinkage at the time of curing and provide excellent planarization of wiring steps.

The above-mentioned benzocyclobutene resins and the epoxyacrylate resins having a fluorene skeleton do not have as high film strength and shear extensibility as the polyimide resins and have no flexibility. This is not disadvantageous for a wiring board alone, but the resins can not endure stresses caused from a large area semiconductor device that is mounted barely in a flip-chip manner, resulting in cracks in the wiring board.

Polybenzoxazole films can be used as interlayer insulators that cause no shrinkage stress and have an excellent moisture resistance, high film strength, high shear extensibility and excellent flexibility. Among those, as disclosed in JP 11-181094A publication, a fluorine-containing polybenzoxazole has an advantageous low dielectric constant and is used as an interlayer insulator for multi-layered wires.

In polybenzoxazole, particularly a fluorine-containing polybenzoxazole, when it is applied as such to an interlayer insulator, its adhesion with a conductive wiring is not sufficient in practice. In addition, a large stress occurs when a semiconductor device is mounted due to a large thermal expansion coefficient. Further, it has a low tear resistance and a poor property for handling. Thus, it is required to improve these problems.

### SUMMARY OF THE INVENTION

An object of the present invention is to provide a wiring board for high dense mounting, which has a high heat resistance, low dielectric constant, low water absorption degree, low thermal expansion coefficient, and high adhesion between conductors and insulators. The wiring board is also excellent in film strength and shear extensibility, capable of enduring a stress in mounting of a semiconductor device, excellent in reliability, and optimal for high speed and high dense mounting.

As a result of intensively studying to solve the above-mentioned object, the present invention is based on the following idea.

Namely, in the present invention, at least one layer of interlayer insulator and at least one layer of conductive wiring pattern are formed on a base material. At least one layer of the interlayer insulator comprises a polybenzoxazole film. An adhesive layer comprising at least one selected from the group consisting of Ti, a Ti-containing compound and Ni is formed between the polybenzoxazole film and the conductive wiring pattern.

The polybenzoxazole, preferably used, may be a compound represented by general formula (1):

[chemical structure]

where 0.05≦n≦0.5; n+m=1; Ar₁, Ar₂, Ar₃ and Ar₄ denote any bifunctional group. The compound represented by the general formula (1) is referred as to a fluorine-containing polybenzoxazole if it contains a fluorine atom in any one of Ar₁, Ar₂, Ar₃ and Ar₄. The fluorine-containing polybenzoxazole is particularly excellent in low dielectric constant and low water absorption degree and desirable in electrical properties while it is poor in adhesion with a conductive wire. Though this problem can be solved in the wiring board for high dense mounting according to the present invention.

In the present invention, upon formation of the polybenzoxazole film on the base material, a thermoplastic polyimide resin film having a glass transition point ranging from 180° C. to 350° C. may be interposed between the base material and the polybenzoxazole film to improve the adhesion therebetween.

The polybenzoxazole film has strength to some extent but it is hard to be handled as a film due to its low tear strength. This problem can be solved by the wiring board for high dense mounting, which comprises a polyimide resin layer with a thickness of at least 10 μm on the base material.

The interlayer insulator formed on the base material may consist of a composite insulator film comprising the polybenzoxazole film and a resin film with a thermal expansion coefficient of 40 ppm or below. This wiring board for high dense mounting can endure a stress and prevent cracks when a semiconductor device is mounted.

Accordingly, a first aspect of the present invention is provided with a wiring board for high dense mounting comprising:

a base material;

at least one layer of interlayer insulator formed on the base material;

an adhesive layer comprising at least one selected from the group consisting of Ti, a Ti-containing compound and Ni and formed on the interlayer insulator; and

a conductive wiring pattern formed on the adhesive layer, wherein the interlayer insulator comprises a polybenzoxazole film.

A second aspect of the present invention is provided with a wiring board for high dense mounting comprising:

a base material;

at least one layer of interlayer insulator formed on the base material;

an adhesive layer comprising at least one selected from the group consisting of Ti, a Ti-containing compound and Ni and formed on the interlayer insulator; and

a conductive wiring pattern formed on the adhesive layer, wherein an interlayer insulator directly connected to the base material comprises a polybenzoxazole film.

Preferred examples of the above-mentioned wiring boards are described hereunder.

In the wiring board for high dense mounting according to the first and second examples, the Ti-containing compound is selected from the group consisting of TiW, TiN and TiC.

The Ti-containing compound has a content of at least 0.1% by weight of W, N and/or C.

The interlayer insulator is laminated alternately with the conductive wiring pattern to form a multi-layered wiring structure.

The polybenzoxazole film is composed of polybenzoxazole represented by general formula (1):

[chemical structure]

where 0.05≦n≦0.5; n+m=1; Ar₁, Ar₂, Ar₃ and Ar₄ denote any bifunctional group.

The wiring board for high dense mounting further comprises a thermoplastic polyimide resin film having a glass transition point ranging from 180° C. to 350° C. interposed between the base material and the polybenzoxazole film directly connected thereto.

The polyimide resin film has a thickness of at least 10 μm.

The interlayer insulator comprises a composite insulator film comprising the polybenzoxazole film and a resin film with a thermal expansion coefficient of 40 ppm or below.

A third aspect of the present invention is provided with a method of producing a wiring board for high dense mounting comprising the steps of:

forming a polybenzoxazole film represented by general formula (1):

[chemical structure]

where 0.05≦n≦0.5; n+m=1; Ar₁, Ar₂, Ar₃ and Ar₄ denote any bifunctional group;

forming an adhesive layer comprising at least one selected from the group consisting of Ti, a Ti-containing compound and Ni on the polybenzoxazole film using any one of spattering, vaporizing and electroless plating processes;

forming a metallic film comprising at least one selected from the group consisting of Cu, Pd, Pt and Au on the adhesive layer;

patterning a photoresist on the metallic film except for a region corresponding to a conductive wiring pattern;

forming a metallic film by electroless plating on a region not masked with the photoresist; and

peeling the photoresist off and etching an excess of the metallic film and then an excess of the adhesive layer to form the conductive wiring pattern.

A fourth aspect of the present invention is provided with a method of producing a wiring board for high dense mounting comprising the steps of:

forming a first polybenzoxazole film comprising a compound represented by general formula (1):

[chemical structure]

where 0.05≦n≦0.5; n+m=1; Ar₁, Ar₂, Ar₃ and Ar₄ denote any bifunctional group;

forming a first adhesive layer comprising at least one selected from the group consisting of Ti, a Ti-containing compound and Ni on the polybenzoxazole film using any one of spattering, vaporizing and electroless plating processes;

forming a metallic film comprising at least one selected from the group consisting of Cu, Pd, Pt and Au on the first adhesive layer;

patterning a photoresist on the metallic film except for a region corresponding to a first conductive wiring pattern;

forming a metallic film by electroless plating on a region not masked with the photoresist;

peeling the photoresist off and etching an excess of the metallic film and then an excess of the adhesive layer to form the first conductive wiring pattern;

forming a second adhesive layer comprising at least one selected from the group consisting of Ti, a Ti-containing compound and Ni on the first conductive wiring pattern using any one of spattering, vaporizing and electroless plating processes in addition to photolithography technology; and

forming a second polybenzoxazole film comprising the compound represented by the general formula (1) on the second adhesive layer.

A fifth aspect of the present invention is provided with a method of producing a wiring board for high dense mounting comprising the steps of:

forming a polyimide resin film on a base material;

forming a conductive wiring pattern on the polyimide resin film to form a support substrate;

forming on a surface of the support substrate at the side of the conductive wiring pattern a polybenzoxazole film comprising a compound represented by general formula (1):

[chemical structure]

where 0.05≦n≦0.5; n+m=1; Ar₁, Ar₂, Ar₃ and Ar₄ denote any bifunctional group; and

forming on the polybenzoxazole film a resin film with a thermal expansion coefficient of 40 ppm or below to form a composite insulator film comprising the polybenzoxazole film and the resin film.

A sixth aspect of the present invention is provided with a method of producing a wiring board for high dense mounting comprising the steps of:

forming a polyimide resin film on a base material;

forming a first conductive wiring pattern on the polyimide resin film to form a support substrate;

forming on a surface of the support substrate at the side of the first conductive wiring pattern a first polybenzoxazole film comprising a compound represented by general formula (1):

[chemical structure]

where 0.05≦n≦0.5; n+m=1; Ar₁, Ar₂, Ar₃ and Ar₄ denote any bifunctional group;

forming on the first polybenzoxazole film a first resin film with a thermal expansion coefficient of 40 ppm or below to form a first composite insulator film comprising the first polybenzoxazole film and the first resin film;

forming a second conductive wiring pattern on the first composite insulator film;

forming a second polybenzoxazole film comprising the compound represented by the general formula (1) on the second conductive wiring pattern; and

forming on the second polybenzoxazole film a second resin film with a thermal expansion coefficient of 40 ppm or below to form a second composite insulator film comprising the second polybenzoxazole film and the second resin film.

Other features and advantages of the invention will be apparent from the following description of the preferred embodiments thereof.

### BRIEF DESCRIPTION OF THE DRAWINGS

The present invention will be more fully understood from the following detailed description with reference to the accompanying drawings.

FIGS. 1A-1E are cross-sectional views showing an embodiment of a process of manufacturing a wiring board for high dense mounting, which comprises at least one layer of interlayer insulator and at least one layer of conductive wiring pattern formed on a base material. At least one layer of the interlayer insulator comprises a polybenzoxazole film. An adhesive layer comprising at least one selected from the group consisting of Ti, a Ti-containing compound and Ni is formed between the polybenzoxazole film and the conductive wiring pattern.

FIGS. 2A-2C are cross-sectional views showing an embodiment of a process of manufacturing a wiring board for high dense mounting, which comprises a thermoplastic polyimide resin film for formation of a polybenzoxazole film on the base material. This resin film has a glass transition point ranging from 180° C. to 350° C. and is interposed between the base material and the polybenzoxazole film.

FIGS. 3A-3C are cross-sectional views showing an embodiment of a process of manufacturing a wiring board for high dense mounting, which comprises a polyimide resin layer with a thickness of at least 10 μm on the base material.

FIGS. 4A-4C are cross-sectional views showing an embodiment of a process of manufacturing a wiring board for high dense mounting, in which the interlayer insulator formed on the base material comprises a composite insulator film. This composite insulator film comprises the polybenzoxazole film and a resin film with a thermal expansion coefficient of 40 ppm or below.

### DETAILED DESCRIPTION OF THE PREFERRED MODES OF EMBODIMENT

The polybenzoxazole of the present invention is a compound represented by the general formula (1), preferably a fluorine-containing polybenzoxazole. As an example of the fluorine-containing polybenzoxazole, Ar₁, Ar₂, Ar₃ and Ar₄ are represented with the following structural formulae.

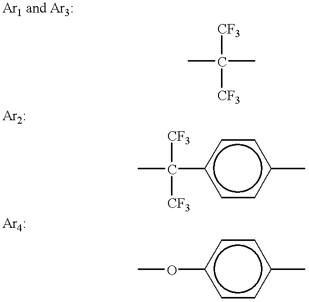

A polybenzoxazole can generally be obtained by cyclodehydration of polyhydroxyamide that results from a reaction between a bis(aminophenol) compound and a dicarboxylic dihalide or dicarboxylic diester.

The fluorine-containing polybenzoxazole represented by the above-mentioned structural formulae can be obtained as follows. First, 4,4′-dicarboxyldiphenylether and 1-hydroxybenzotriazole are used to synthesize an active ester. Next, 2,2-bis(4-carboxyphenyl)hexafluoropropane and 1-hydroxybenzotriazole are used to synthesize an ester. This ester is subjected to a reaction with 2,2-bis(3-amino-4-hydroxyphenyl) hexafluoropropane. To this reacted solution, the previously synthesized active ester is added to synthesize a fluorine-containing polybenzoxazole through their reaction.

The present invention will be described hereunder with reference to the drawings.

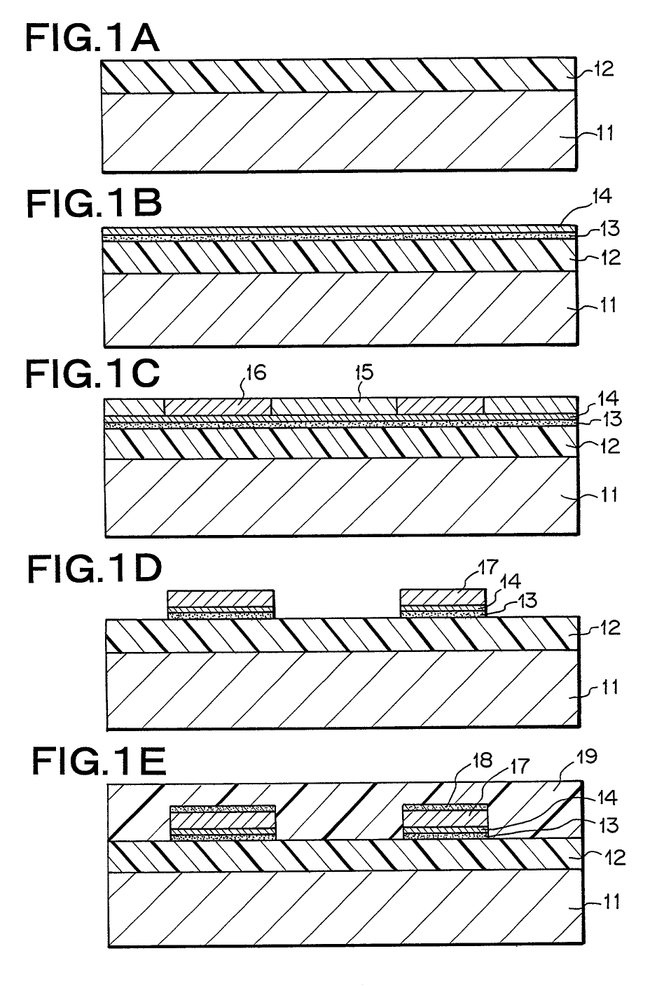

FIGS. 1A-1E are cross-sectional views showing an embodiment of a process of manufacturing a support substrate, that is, a wiring board for high dense mounting, which comprises at least one layer of interlayer insulator and at least one layer of conductive wiring pattern. At least one layer of the interlayer insulator comprises a polybenzoxazole film. An adhesive layer comprising at least one selected from the group consisting of Ti, a Ti-containing compound and Ni is formed between the polybenzoxazole film and the conductive wiring pattern.

On a base material 11, a polybenzoxazole film 12 is formed using a polybenzoxazole represented by the above-mentioned general formula (1) (FIG. 1A). Next, an adhesive layer 13 comprising at least one selected from the group consisting of Ti, a Ti-containing compound and Ni is formed thereon using a process of spattering, vaporizing or electroless etching. Then, a metallic film 14 consisting of Cu, Pd, Pt or Au is formed thereon similarly (FIG. 1B). Thereafter, a photoresist 15 is patterned to exclude a region to be a conductive wiring pattern. Then, a plated metallic film 16 consisting of Cu or other substances is deposited on a region not masked with the photoresist using electroplating (FIG. 1C). Finally, the photoresist 15 is peeled, and the exposed metallic film 14 and then the adhesive layer 13 are etched to form a conductive wiring pattern 17 and to complete the wiring board for high dense mounting (FIG. 1D).

In forming a wiring board for high dense mounting with a multi-layered structure, it is effective to form another adhesive layer 18 on the conductive wiring pattern 17 and then another polybenzoxazole film 19 as an insulator, if required (FIG. 1E). The adhesive layer 18 is formed of at least one selected from the group consisting of Ti, a Ti-containing compound and Ni using a spattering, vaporizing or electroless plating process in addition to photolithography technology.

Cr and Mo are well known as an adhesive layer that is used in formation of a conductive wiring pattern on the polyimide resin. It is found on the other hand that a nice adhesive can be obtained when an adhesive layer consisting of Ti, a Ti-containing compound or Ni is applied on the polybenzoxazole film. In particular, it is found that a nice adhesive can be obtained between the base material and the polybenzoxazole film when a Ti-containing compound, TiW, TiN or TiC, is applied with an additive content of at least 0.1% by weight of W, N and C. That product is optimal for a material for the adhesive layer 13.

The base material 11 is composed of any material, not limited in particular, that includes a variety of metal, resin, printed board, ceramic, glass and Si, and may not be only rigid but also in the form of a film. The wiring board for high dense mounting of the present invention may also be effective if the base material is not prepared in particular and the conductive wiring pattern 16 is formed directly on the polybenzoxazole film 12 in the form of a film. Alternatively, the base material 11 may be removed finally from the wiring board.

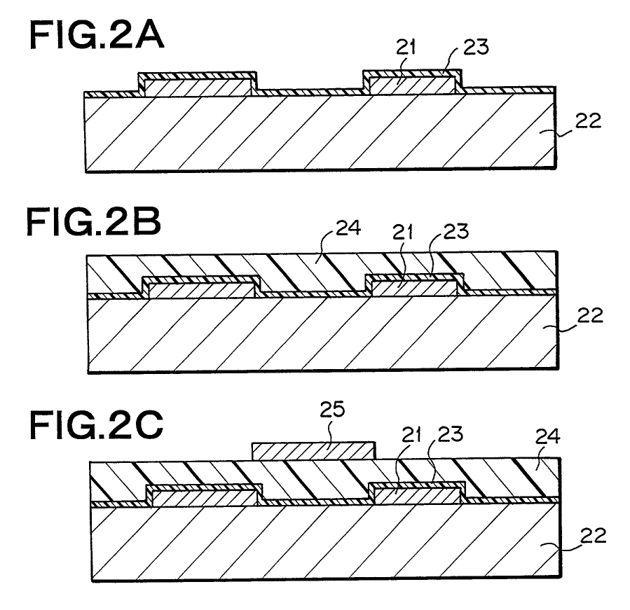

FIGS. 2A-2C are cross-sectional views showing an embodiment of a process of manufacturing a wiring board for high dense mounting, which comprises a thermoplastic polyimide resin film for formation of a polybenzoxazole film on the base material. This resin film has a glass transition point ranging from 180° C. to 350° C. and is interposed between the base material and the polybenzoxazole film.

A thermoplastic polyimide resin layer 23 is formed on a base material 22 that has a conductive wiring pattern 21 thereon (FIG. 2A). The polyimide resin layer 23 has a thickness of 0.01-10 μm, preferably 1 μm and a glass transition point ranging from 180° C. to 350° C. A polybenzoxazole film 24 is formed next (FIG. 2B). Thereafter, in accordance with the method of the present invention as described in FIGS. 1A-1E, a conductive wiring pattern 25 is formed on the polybenzoxazole film 24 to complete a wiring board for high dense mounting (FIG. 2C).

The thermoplastic polyimide resin exhibits adhesion when it is heated. Thus, formation of a film comprising the resin can provide a wiring board for high dense mounting, which is excellent in adhesion between the polybenzoxazole film 24 and the conductive wiring pattern 21 or base material 22. It is found that the thermoplastic polyimide resin layer 23 has a glass transition point appropriately ranging from 180° C. to 350° C. If a resin with a glass transition point below 180° C. is applied thereto, a problem arises on heat resistance to cause interlayer peeling and expanding during solder ref lowing and semiconductor device mounting processes. To the contrary, if a resin with a glass transition point above 350° C. is applied thereto, a sufficient adhesive strength can not be obtained. Because the polybenzoxazole film 24 has a curing temperature of about 300° C. that is below the glass transition point.

A polyimide resin that is thermoplastic itself may be applied to the thermoplastic polyimide resin layer 23. Alternatively, a mixture of a polyimide resin as a base that is not thermoplastic itself and a thermoplastic component may be used to provide thermoplasticity to the polyimide resin.

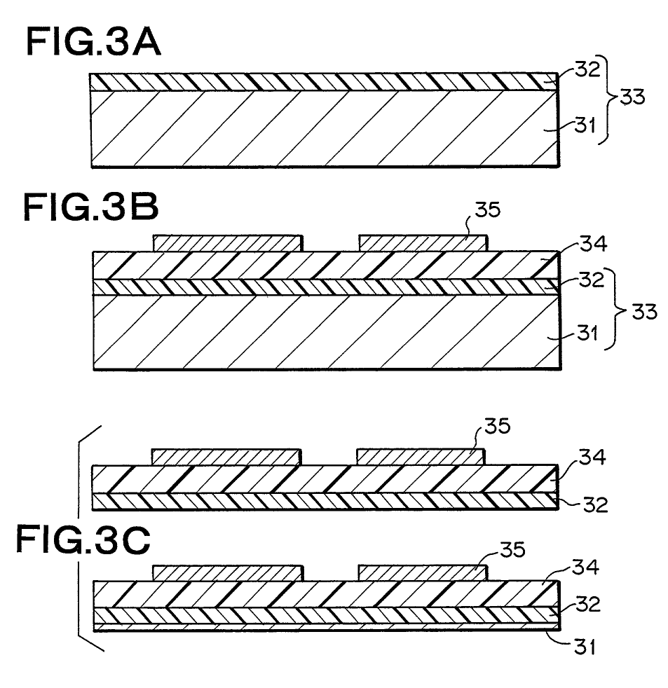

FIGS. 3A-3C are cross-sectional views showing an embodiment of a process of manufacturing a wiring board for high dense mounting, which comprises a polyimide resin layer with a thickness of at least 10 μm on the base material. This is similar to those illustrated in FIGS. 1A-1E or 2A-2C of the present invention.

A polyimide resin layer 32 with a thickness of at least 10 μm is formed on a base material 31 to form a support substrate 33 having a polyimide resin layer with a thickness of at least 10 μm (FIG. 3A). Next, in accordance with the method of the present invention as described in FIGS. 1A-1E or 2A-2C, a polybenzoxazole film 34 is formed as an insulator on the polyimide resin layer 32 and a conductive wiring pattern 35 is formed thereon (FIG. 3B). Finally, the base material 31 is removed completely or thinned by an etching or polishing process to finish a wiring board for high dense mounting in the form of a film (FIG. 3C).

The polybenzoxazole film has small strength but weak tear strength and it is hard to be handled as a wiring board for high dense mounting in the form of a film. The polyimide resin layer, which is excellent in both film strength and tear strength, can be used as the base material to form a wiring board for high dense mounting in the form of a film with a sufficient tear strength.

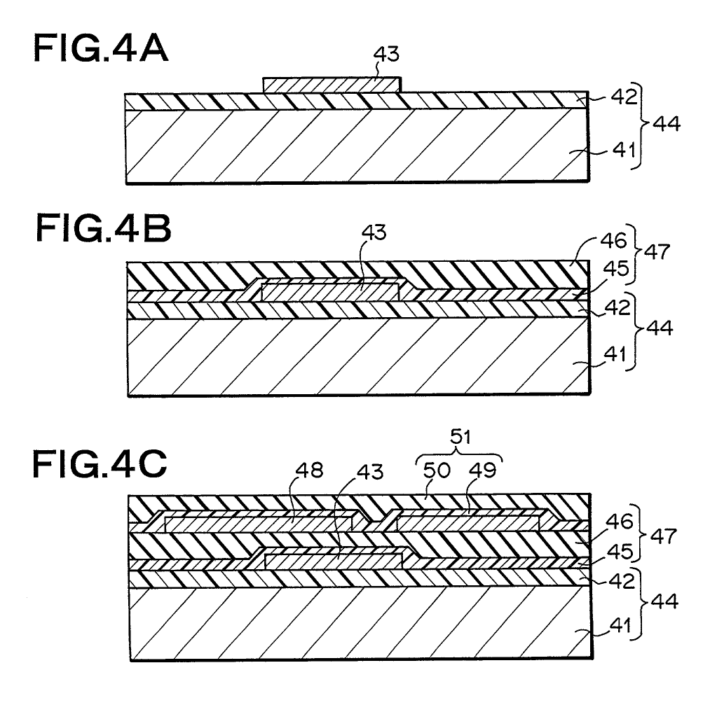

FIGS. 4A-4C are cross-sectional views showing an embodiment of a process of manufacturing a wiring board for high dense mounting, in which the interlayer insulator formed on the base material comprises a composite insulator film. This composite insulator film comprises the polybenzoxazole film and a resin film with a thermal expansion coefficient of 40 ppm or below.

On a base material 41, a polyimide resin layer 42 and then a conductive wiring pattern 43 are formed to prepare a support substrate 44 (FIG. 4A). Next, a first polybenzoxazole film 45 is formed on a surface of the support substrate 44 at the side of the conductive wiring pattern 43. Then, a resin film 46 with a thermal expansion coefficient of 40 ppm is formed thereon to form a wiring board for high dense mounting that has a composite insulator film 47 (FIG. 4B). Further, another conductive wiring pattern 48 is formed on the composite insulator film 47, if required. In addition, another composite insulator film 51 comprising a second polybenzoxazole film 49 and a resin film 50 with a thermal expansion coefficient of 40 ppm or below is formed thereon. Thereafter, these processes may be repeated to form an insulator film with a multi-layered composite structure in the wiring board for high dense mounting (FIG. 4C).

The polybenzoxazole film has a large thermal expansion coefficient. In particular, if the wiring board for high dense mounting has a multi-layered structure, a large stress works on it when a semiconductor device is mounted. This bends the wiring board and cracks the polybenzoxazole film. It is found that these problems can be solved through the use of the composite insulator film comprising the polybenzoxazole film and the resin film with a thermal expansion coefficient of 40 ppm.

The resin film with a thermal expansion coefficient of 40 ppm may include a film of polyimide resin, benzocyclobutene resin or epoxyacrylate resin having a fluorene skeleton. Among those, the epoxyacrylate resin having the fluorene skeleton is excellent in planarization of wiring steps and suitable for formation of a multi-layered structural wiring board for high dense mounting.

According to the present invention, there is provided a wiring board for high dense mounting, which has a high heat resistance, low dielectric constant, low water absorption degree, low thermal expansion coefficient, and high adhesion between conductors and insulators. The wiring board is also excellent in film strength and shear extensibility, capable of enduring a stress in mounting of a semiconductor device, excellent in reliability and high speed, and optimal for high speed and high dense mounting. As a result, a high speed and high dense module or system can be realized.

Having described the embodiments consistent with the invention, other embodiments and variations consistent with the invention will be apparent to those skilled in the art. Therefore, the invention should not be viewed as limited to the disclosed embodiments but rather should be viewed as limited only by the spirit and scope of the appended claims.

What is claimed is:

1. A wiring board for high dense mounting comprising:
a base material;
at least one layer of interlayer insulator formed on said base material;
an adhesive layer comprising at least one selected from the group consisting of Ti, a Ti-containing compound and Ni and formed on said interlayer insulator; and
a conductive wiring pattern formed on said adhesive layer, wherein said interlayer insulator comprises a polybenzoxazole film.

2. The wiring board for high dense mounting according to claim 1, wherein said interlayer insulator is laminated alternately with said conductive wiring pattern to form a multi-layered wiring structure.

3. A wiring board for high dense mounting comprising:
a base material;
at least one layer of interlayer insulator formed on said base material;
an adhesive layer comprising at least one selected from the group consisting of Ti, a Ti-containing compound and Ni and formed on said interlayer insulator; and
a conductive wiring pattern formed on said adhesive layer, wherein an interlayer insulator directly connected to said base material comprises a polybenzoxazole film.

4. The wiring board for high dense mounting according to claim 3, wherein said Ti-containing compound is selected from the group consisting of TiW, TiN and TiC.

5. The wiring board for high dense mounting according to claim 4, wherein said Ti-containing compound has a content of at least 0.1% by weight of W, N and/or C.

6. The wiring board for high dense mounting according to claim 3, wherein said interlayer insulator is laminated alternately with said conductive wiring pattern to form a multi-layered wiring structure.

7. The wiring board for high dense mounting according to any one of claims 1-6, wherein said polybenzoxazole film is composed of polybenzoxazole represented by general formula (1): [chemical structure]
where 0.05≦n≦0.5; n+m=1; Ar₁, Ar₂, Ar₃ and Ar₄ denote any bifunctional group.

8. The wiring board for high dense mounting according to claim 7, further comprising a thermoplastic polyimide resin film having a glass transition point ranging from 180° C. to 350° C. interposed between said base material and said polybenzoxazole film directly connected thereto.

9. The wiring board for high dense mounting according to claim 8, wherein said polyimide resin film has a thickness of at least 10 μm.

10. The wiring board for high dense mounting according to claim 9, wherein said interlayer insulator comprises a composite insulator film comprising said polybenzoxazole film and a resin film with a thermal expansion coefficient of 40 ppm or below.

11. A method of producing a wiring board for high dense mounting comprising the steps of:
forming a polybenzoxazole film represented by general formula (1): [chemical structure]
where 0.05≦n≦0.5; n+m=1; Ar₁, Ar₂, Ar₃ and Ar₄ denote any bifunctional group;
forming an adhesive layer comprising at least one selected from the group consisting of Ti, a Ti-containing compound and Ni on said polybenzoxazole film using any one of spattering, vaporizing and electroless plating processes;
forming a metallic film comprising at least one selected from the group consisting of Cu, Pd, Pt and Au on said adhesive layer;
patterning a photoresist on said metallic film except for a region corresponding to a conductive wiring pattern;
forming a metallic film by electroless plating on a region not masked with said photoresist; and
peeling said photoresist off and etching an excess of said metallic film and then an excess of said adhesive layer to form said conductive wiring pattern.

12. A method of producing a wiring board for high dense mounting comprising the steps of:
forming a first polybenzoxazole film comprising a compound represented by general formula (1): [chemical structure]
where 0.05≦n≦0.5; n+m=1; Ar₁, Ar₂, Ar₃ and Ar₄ denote any bifunctional group;
forming a first adhesive layer comprising at least one selected from the group consisting of Ti, a Ti-containing compound and Ni on said polybenzoxazole film using any one of spattering, vaporizing and electroless plating processes;
forming a metallic film comprising at least one selected from the group consisting of Cu, Pd, Pt and Au on said first adhesive layer;
patterning a photoresist on said metallic film except for a region corresponding to a first conductive wiring pattern;
forming a metallic film by electroless plating on a region not masked with said photoresist;
peeling said photoresist off and etching an excess of said metallic film and then an excess of said adhesive layer to form said first conductive wiring pattern;
forming a second adhesive layer comprising at least one selected from the group consisting of Ti, a Ti-containing compound and Ni on said first conductive wiring pattern using any one of spattering, vaporizing and electroless plating processes in addition to photolithography technology; and
forming a second polybenzoxazole film comprising said compound represented by said general formula (1) on said second adhesive layer.

13. A method of producing a wiring board for high dense mounting comprising the steps of:
forming a polyimide resin film on a base material;
forming a conductive wiring pattern on said polyimide resin film to form a support substrate;
forming on a surface of said support substrate at the side of said conductive wiring pattern a polybenzoxazole film comprising a compound represented by general formula (1): [chemical structure]
where 0.05≦n≦0.5; n+m=1; Ar₁, Ar₂, Ar₃ and Ar₄ denote any bifunctional group; and
forming on said polybenzoxazole film a resin film with a thermal expansion coefficient of 40 ppm or below to form a composite insulator film comprising said polybenzoxazole film and said resin film.

14. A method of producing a wiring board for high dense mounting comprising the steps of:
forming a polyimide resin film on a base material;
forming a first conductive wiring pattern on said polyimide resin film to form a support substrate;
forming on a surface of said support substrate at the side of said first conductive wiring pattern a first polybenzoxazole film comprising a compound represented by general formula (1): [chemical structure]
where 0.05≦n≦0.5; n+m=1; Ar₁, Ar₂, Ar₃ and Ar₄ denote any bifunctional group;
forming on said first polybenzoxazole film a first resin film with a thermal expansion coefficient of 40 ppm or below to form a first composite insulator film comprising said first polybenzoxazole film and said first resin film;
forming a second conductive wiring pattern on said first composite insulator film;
forming a second polybenzoxazole film comprising said compound represented by said general formula (1) on said second conductive wiring pattern; and
forming on said second polybenzoxazole film a second resin film with a thermal expansion coefficient of 40 ppm or below to form a second composite insulator film comprising said second polybenzoxazole film and said second resin film.
